(19) United States
(12) Patent Application Publication
(10) Pub. No.: US 2014/0029201 A1
(43) Pub. Date: Jan. 30, 2014

(54) POWER PACKAGE MODULE AND MANUFACTURING METHOD THEREOF

(71) Applicants: Si Joong YANG, Suwon (KR); Do Jae Yoo, Suwon (KR); Joon Seok Chae, Suwon (KR)

(72) Inventors: Si Joong YANG, Suwon (KR); Do Jae Yoo, Suwon (KR); Joon Seok Chae, Suwon (KR)

(21) Appl. No.: 13/620,608

(22) Filed: Sep. 14, 2012

(30) Foreign Application Priority Data
Jul. 25, 2012 (KR) 10-2012-0081466

(51) Int. Cl. H05K 7/14; H05K 3/30; H05K 7/20

(52) U.S. Cl. 361/707; 361/813; 361/748; 29/832

(57) ABSTRACT

There is provided a power package module, including: a lead frame; at least one first electronic component mounted on the lead frame; and an insulating member disposed on a first surface of the first electronic component and having a via electrode connected to the first electronic component.

### CROSS-REFERENCE TO RELATED APPLICATIONS

This application claims the priority of Korean Patent Application No. 10-2012-0081466 filed on Jul. 25, 2012, in the Korean Intellectual Property Office, the disclosure of which is incorporated herein by reference.

### BACKGROUND OF THE INVENTION

1. Field of the Invention

The present invention relates to a power package module and a manufacturing method thereof, and more particularly, to a power package module in which electronic components mounted on the inside thereof and a lead frame are easily connected to each other, and a manufacturing method thereof.

2. Description of the Related Art

A power package module includes a lead frame and electronic components. The electronic component is mounted on the lead frame and is electrically connected to the lead frame by wire bonding.

A connection structure by the wire bonding is valid even in a comparatively small-sized module. However, as the number of the electronic components and the number of connection terminals mounted on the lead frame have gradually increased, operational efficiency of the structure connected by the wire bonding deteriorates.

The related art associated therewith includes Patent Document 1 and Patent Document 2. Herein, Patent Document 1 illustrates a structure for reducing heat resistance, but does not present a definite configuration which may substitute for wire bonding.

Unlike this, Patent Document 2 discloses a structure in which a semiconductor device 1 and terminals 6 and 7 are connected to each other through an electrode of a through-hole 13 formed on a substrate. However, in the structure, since a solder ball needs to be used in order to electrically connect the electrode of the through-hole 13 and the semiconductor device 1, it may be difficult to expect an improvement in manufacturing speed.

### RELATED ART DOCUMENT

(Patent Document 1) JP2009-177038 A
(Patent Document 2) JP2004-172211 A

### SUMMARY OF THE INVENTION

An aspect of the present invention provides a power package module in which electronic components and a lead frame may be easily connected to each other, and a manufacturing method thereof.

According to an aspect of the present invention, there is provided a power package module including: a lead frame; at least one first electronic component mounted on the lead frame; and an insulating member disposed on a first surface of the first electronic component and having a via electrode connected to the first electronic component, wherein the via electrode extends to the first surface.

The insulating member may include a plurality of through holes, each being provided for forming the via electrode.

The insulating member may be a printed circuit board (PCB).

The insulating member may include a circuit pattern connecting the via electrode and the lead frame.

The via electrode may be formed of a conductive material that integrally connects the first electronic component and the circuit pattern.

The insulating member may include a through hole for forming the via electrode and a pattern groove for forming a circuit pattern.

The through hole and the pattern groove may be filled with a conductive material.

The insulating member may have a second electronic component mounted thereon.

The second electronic component may include a passive element.

The power package module may further include a heat dissipating member attached to the lead frame to dissipate heat generated from the electronic component to the outside.

According to another aspect of the present invention, there is provided a power package module including: a heat dissipating member; at least one first electronic component mounted on the heat dissipating member; an insulating member disposed on a first surface of the first electronic component and having a via electrode connected to the first electronic component; and a lead frame connected to the insulating member, wherein the via electrode extends to the first surface.

The insulating member may include a plurality of through holes, each being provided for forming the via electrode.

The insulating member may be a PCB.

The insulating member may include a circuit pattern connecting the via electrode and the lead frame.

The via electrode may be formed of a conductive material that integrally connects the first electronic component and the circuit pattern.

The insulating member may include a through hole for forming the via electrode and a pattern groove for forming a circuit pattern.

The through hole and the pattern groove may be filled with a conductive material.

The insulating member may have a second electronic component mounted thereon.

The second electronic component may include a passive element.

According to yet another aspect of the present invention, there is provided a manufacturing method of a power package module, the manufacturing method including: mounting at least one electronic component on a lead frame; disposing a circuit pattern connected to the lead frame and an insulating member provided with a through hole on a first surface of the electronic component; and forming a via electrode connecting the electronic component and the circuit pattern by filling the through hole with a conductive material.

The through hole may be filled with the conductive material by a squeezing process.

According to another aspect of the present invention, there is provided a manufacturing method of a power package module, the manufacturing method including: mounting a heat dissipating member on a lead frame; mounting at least one electronic component on the heat dissipating member; disposing an insulating member provided with a pattern groove and a through hole on a first surface of the electronic component; and forming a connection circuit connecting the electronic component and the lead frame by filling the pattern groove and the through hole with a conductive material.

The pattern groove and the through hole may be filled with the conductive material by a squeezing process.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a power package module according to a first embodiment of the present invention;

FIG. 2 is a plan view illustrating a form of an insulating member illustrated in FIG. 1;

FIG. 3 is a plan view illustrating another form of the insulating member illustrated in FIG. 1;

FIG. 4 is a cross-sectional view of a power package module according to a second embodiment of the present invention;

FIG. 5 is a cross-sectional view of a power package module according to a third embodiment of the present invention;

FIG. 6 is a cross-sectional view of a power package module according to a fourth embodiment of the present invention;

FIG. 7 is a cross-sectional view of a power package module according to a fifth embodiment of the present invention;

FIG. 8 is a diagram illustrating a manufacturing method of the power package module according to the first embodiment of the present invention; and

FIG. 9 is a diagram illustrating a manufacturing method of the power package module according to the second embodiment of the present invention.

### DETAILED DESCRIPTION OF THE INVENTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

A power package module may include a plurality of electronic components and the electronic components may be electrically connected to a lead frame by wire bonding. However, the connection structure of the electronic components and the lead frame may have the following limitations.

First, a manufacturing period required to connect the plurality of electronic components and the lead frame may be relatively long.

The electrical connection by wire bonding is achieved by individually connecting connection terminals of the electronic components and connection terminals of the lead frame. Therefore, when the plurality of electronic components are mounted on the power package module, the manufacturing period required to connect the electronic component and the lead frame is extended, and as a result, production efficiency of the power package module may deteriorate.

Second, inductance of the power package module may increase.

Through wire bonding, the connection terminal of the electronic component and the connection terminal of the lead frame may not be connected in a linear form, but connected in a curved form, due to structural characteristics. Since the connection structure may allow for an extended connection distance between the connection terminal of the electronic component and the connection terminal of the lead frame, the connection structure increases inductance.

Therefore, it is difficult to use the power package module having a wire bonding structure in electronic equipment requiring low inductance.

The present invention is intended to solve the limitation and an object thereof is to provide a power package module that can be manufactured through a simple manufacturing process and have low inductance. To this end, in the present invention, the electronic component and the lead frame may be connected to each other by an insulating member provided with a via electrode and a circuit pattern.

In describing the present invention below, since terms indicating components of the present invention are named by considering functions of the respective components, the terms should not be appreciated as having meanings defining technical components of the present invention.

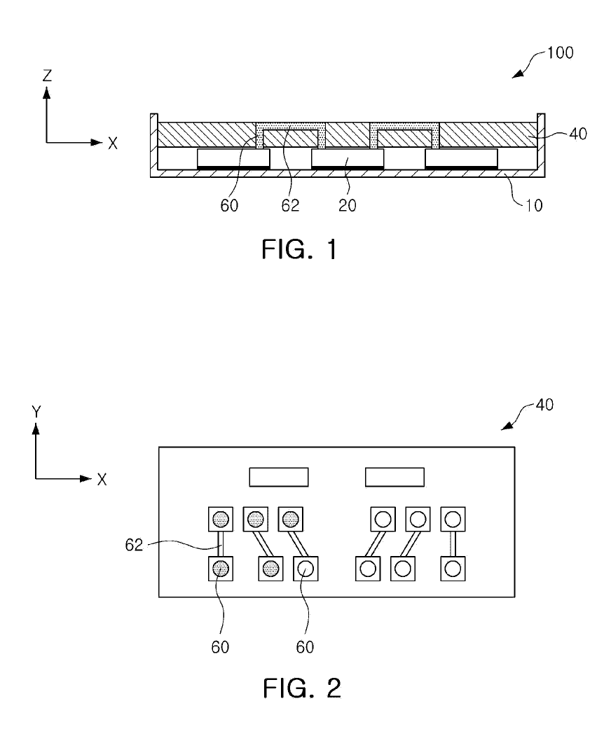

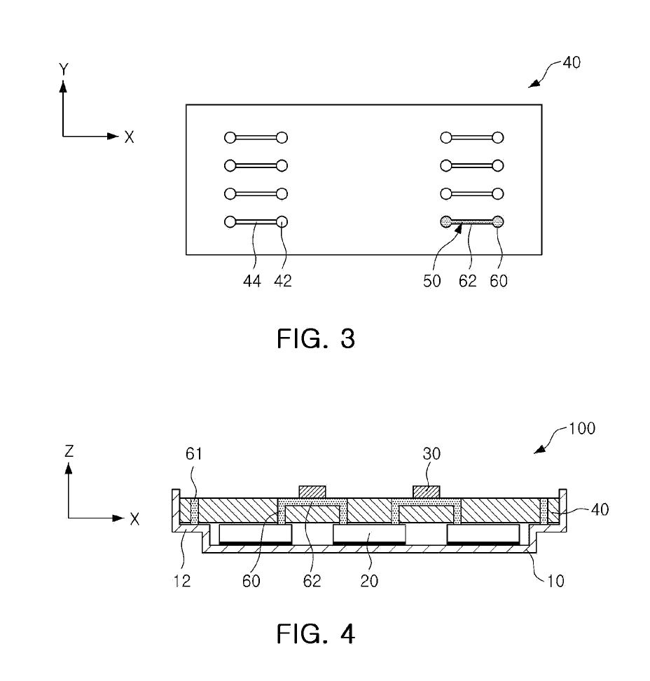

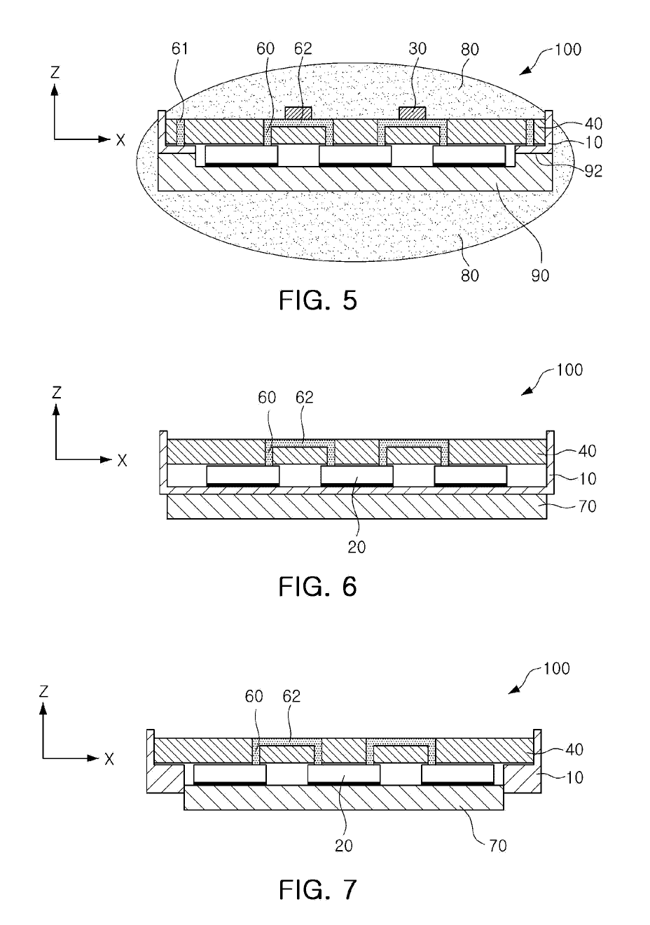

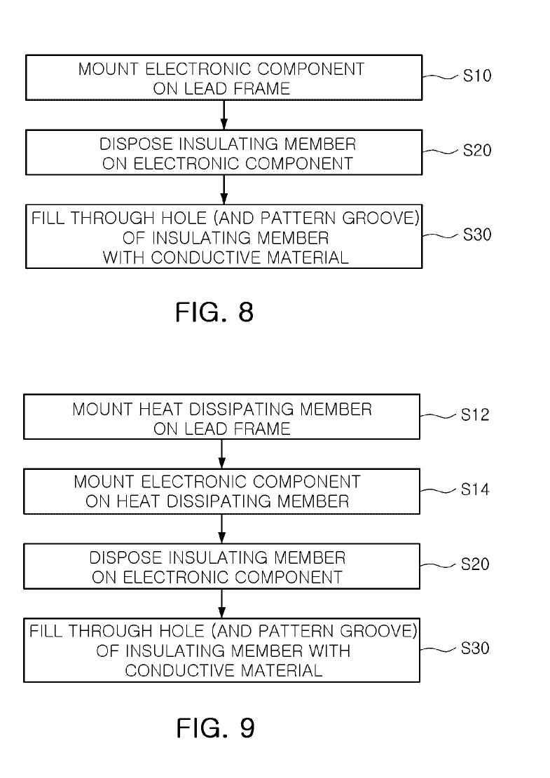

FIG. 1 is a cross-sectional view of a power package module according to a first embodiment of the present invention; FIG. 2 is a plan view illustrating a form of an insulating member illustrated in FIG. 1; FIG. 3 is a plan view illustrating another form of the insulating member illustrated in FIG. 1; FIG. 4 is a cross-sectional view of a power package module according to a second embodiment of the present invention; FIG. 5 is a cross-sectional view of a power package module according to a third embodiment of the present invention; FIG. 6 is a cross-sectional view of a power package module according to a fourth embodiment of the present invention; FIG. 7 is a cross-sectional view of a power package module according to a fifth embodiment of the present invention; FIG. 8 is a diagram illustrating a manufacturing method of the power package module according to the first embodiment of the present invention; and FIG. 9 is a diagram illustrating a manufacturing method of the power package module according to the second embodiment of the present invention.

The power package module according to the first embodiment of the present invention will hereinafter be described with reference to FIGS. 1 through 3.

A power package module 100, according to the first embodiment, may include a lead frame 10, at least one first electronic component 20, and an insulating member 40. Moreover, the power package module 100 may further include a resin member 80.

The lead frame 10 may be made of a metallic material. For example, the lead frame 10 may be manufactured by press-processing a metallic thin plate. The lead frame 10 may provide a space in which at least one first electronic component 20 may be mounted. Moreover, the lead frame 10 may include a plurality of leads to be electrically connected to the at least one first electronic component 20 or other components. Herein, the leads may be discriminated as an inner lead and an outer lead. For example, the inner lead may be connected to the first electronic component 20 mounted on the lead frame 10 and the outer lead may be connected to another package module. Meanwhile, a shape of the lead frame 10 may be changed depending on a type of the power package module 100 to be manufactured.

The first electronic component 20 may be mounted on the lead frame 10. The first electronic component 20 may be disposed in the center of the lead frame 10 and may be electrically connected to the lead. Herein, the first electronic component 20 and the lead may be electrically connected to each other by the insulating member 40. The electrical connection will hereinafter be described in detail in a part associated with the insulating member 40. The first electronic component 20 may be an insulated gate bipolar transistor (IGBT), a free-wheeling diode (FWD), and the like. However, the first electronic component 20 is not limited to the aforementioned types of electronic component and may be substituted with other types of electronic component.

The at least one first electronic component 20 mounted on the lead frame 10 may be provided in plural and the plurality of first electronic components have the same height. For example, heights from a top surface of the lead frame 10 to top surfaces of the plurality of first electronic components 20 may be the same. A connection pad may be formed on the top surface of each of the plurality of the first electronic components 20. The connection pad may have a predetermined size and may be electrically connected to a via electrode.

The insulating member 40 may be disposed on the top surfaces of the first electronic components 20. In detail, a bottom surface of the insulating member 40 may contact the top surfaces of the first electronic components 20. The insulating member 40 may be made of an insulating material. For example, the insulating member 40 may be a ceramic substrate, a resin substrate, or a silicon substrate. Moreover, the insulating member 40 may be a printed circuit board provided with a circuit pattern.

The insulating member 40 may include via electrodes 60 and circuit patterns 62. The via electrodes 60 may be formed in a thickness direction of the insulating member 40 and may be electrically connected to the first electronic components 20. The circuit patterns 62 may be formed on the top surface of the insulating member 40. Each of the circuit patterns 62 may be selectively connected to the plurality of via electrodes 60. Moreover, the circuit patterns 62 may electrically connect the via electrodes 60 and the leads of the lead frame 10. Therefore, one first electronic component 20 may be electrically connected to another first electronic component 20 or the lead of the lead frame 10 by the via electrode 60 and the circuit pattern 62.

Meanwhile, the insulating member 40 may be a printed circuit board as illustrated in FIG. 2. In this case, the via electrodes 60 may be made of a conductive material filled in through holes 42 and as the circuit patterns 62, patterns previously printed during a manufacturing process of the printed circuit board may be used as is.

Unlike this, the insulating member 40 may be a substrate provided with a plurality of the through holes 42 and pattern grooves 44, as illustrated in FIG. 3. In this case, the via electrodes 60 may be made of the conductive material filled in the through holes 42 and the circuit patterns 62 may be formed by filling the pattern grooves 44 with the conductive material. Herein, the through holes 42 and the pattern grooves 44 may be formed by laser processing. Moreover, the through holes 42 and the pattern grooves 44 may be simultaneously filled with the conductive material by a squeezing process. That is, the via electrodes 60 and the circuit patterns 62 according to the embodiment may be simultaneously formed in a single process.

Therefore, according to the embodiment, the plurality of first electronic components 20 and the plurality of first electronic components 20 or the plurality of first electronic components 20 and the leads of the lead frame 10 may be promptly and accurately connected by the via electrodes 60 and the circuit patterns 62 formed as above.

The embodiment configured as above has the following advantages.

First, an electrical connection between the first electronic components 20 and the lead frame 10 may be facilitated.

According to the embodiment, the via electrodes 60 and the circuit patterns 62 are simultaneously formed by the squeezing process and the plurality of first electronic components 20 and the leads of the lead frame 10 may be electrically connected to each other by the via electrodes 60 and the circuit patterns 62 formed as above, and as a result, the electrical connection between the first electronic components 20 and the lead frame 10 may be promptly and easily performed.

Second, connection reliability between the first electronic components 20 and the lead frame 10 may be improved.

According to the embodiment, since the first electronic components 20 and the lead frame 10 are connected to each other by the via electrodes 60 and the circuit patterns 62 having a diameter relatively larger than that of a wire, connection force between the first electronic components 20 and the lead frame 10 may be significantly improved.

Moreover, since the via electrodes 60 are formed directly on the top surfaces of the first electronic components 20 due to the conductive material filled in the through holes 42 in a state in which the insulating member 40 is disposed on the top surfaces of the first electronic components 20, the via electrodes 60 may be effectively connected to the first electronic components 20 without an additional solder ball.

Therefore, according to the present embodiment, connection reliability between the first electronic components 20 and the lead frame 10 may be improved and the connection structure between the first electronic components 20 and the lead frame 10 may be simplified.

Third, inductance of the power package module may be reduced.

According to the embodiment, since the first electronic components 20 and the lead frame 10 are electrically connected to each other by the via electrodes 60 and the circuit patterns 62 having a relatively lower resistance than that of a wire, the inductance of the power package module may be reduced.

Accordingly, the power package module 100 according to the embodiment may be suitable for electronic equipment requiring low inductance.

Next, another embodiment of the present invention will hereinafter be described. For reference, the same reference numerals as in the first embodiment refer to the same components as those of the first embodiment described below and accordingly, a detailed description thereof will be omitted.

Hereinafter, a power package module according to a second embodiment of the present invention will be described with reference to FIG. 4.

The power package module 100 according to the second embodiment may be distinguished from that of the first embodiment in that the power package module 100 according to the second embodiment further has a shape of the lead frame 10 and a second electronic component 30.

The lead frame 10 may further include a bent portion 12 that may support the insulating member 40. The bent portion 12 may be formed by press-processing the lead frame 10. Herein, the bent portion 12 may be connected to a via electrode 60 of the insulating member 40.

The second electronic component 30 may be mounted on the top surface of the insulating member 40. The second electronic component 30 may be the same type of component as the first electronic component 20. However, the second electronic component 30 may be a different type of component from the first electronic component 20 if necessary. For example, the second electronic component 30 may include a passive element.

In the power package module 100 configured as above, since a plurality of electronic components may even be mounted on the top surface of the insulating member 40, the power package module 100 may be miniaturized.

A power package module according to a third embodiment of the present invention will hereinafter be described with reference to FIG. 5.

The power package module 100 according to the third embodiment may be discriminated from those of the aforementioned embodiments in that the power package module 100 further includes a housing 90.

The housing 90 may accommodate the plurality of first electronic components 20 therein. To this end, one surface of the housing 90 may be opened.

The lead frame 10 may be disposed on a top surface of the housing 90. In detail, the lead frame 10 may be disposed on end portions 92 of the housing 90.

The insulating member 40 may be mounted on the lead frame 10 and may be electrically connected thereto. To this end, an additional connection terminal may be formed on the bottom surface of the insulating member 40.

Meanwhile, the power package module 100 according to the embodiment may be covered with a resin member 80. The resin member 80 may cover all portions of the power package module 100 except for a part of the lead frame 10. The resin member 80 formed as above may protect the power package module 100 from external impacts.

A power package module according to a fourth embodiment of the present invention will hereinafter be described with reference to FIG. 6.

The power package module 100 according to the fourth embodiment may be discriminated from those of the aforementioned embodiments in that the power package module 100 further includes a heat dissipating member 70.

The heat dissipating member 70 may be disposed on the bottom surface of the lead frame 10. The heat dissipating member 70 may be adhered to the lead frame 10 by a conductive adhesive. For example, the heat dissipating member 70 may be bonded to the lead frame 10 by an anisotropic conductive film (ACF).

The heat dissipating member 70 may dissipate heat generated from the first electronic component 10 to the outside. For example, the heat dissipating member 70 takes heat from the lead frame 10 heated by the first electronic component 10 to dissipate the heat to the outside. To this end, the heat dissipating member 70 may be made of a material having high heat conductivity. For example, the heat dissipating member 70 may be manufactured by aluminum or an alloy including aluminum.

In the power package module 100 configured as above, an increase in temperature of the first electronic component 20 may be suppressed by the heat dissipating member 70. Accordingly, the power package module 100 according to the embodiment may effectively prevent a deterioration in performance due to overheating.

A power package module according to a fifth embodiment of the present invention will hereinafter be described with reference to FIG. 7.

The power package module 100 according to the fifth embodiment may be distinguished from those of the aforementioned embodiment in terms of a disposition structure of the first electronic components 20. That is, the first electronic components 20 may be disposed on the heat dissipating member 70.

The lead frame 10 may be coupled to the heat dissipating member 70. To this end, the lead frame 10 may include a hole into which the heat dissipating member 70 may be inserted.

The heat dissipating member 70 may be coupled to the lead frame 10 and may contact the plurality of first electronic components 20. The heat dissipating member 70 disposed as above, directly receives the heat generated from the first electronic components 20 to dissipate the received heat to the outside.

In the power package module 100 configured as above, since the heat dissipating member 70 and the plurality of first electronic components 20 directly contact each other, a heat dissipation effect through the heat dissipating member 70 may be significantly increased.

Next, a manufacturing method of the power package module according to the embodiment of the present invention will hereinafter be described.

The manufacturing method of the power package module according to the embodiment of the present invention will hereinafter be described with reference to FIG. 8.

The manufacturing method of the power package module according to the embodiment may include mounting an electronic component (S10), disposing an insulating member (S20), and filling a conductive material (S30).

1) Mounting Electronic Component (S10)

In this process, at least one first electronic component 20 may be mounted on the lead frame 10. Here, the first electronic component 20 may be provided in plural and a plurality of first electronic components 20 may be mounted on the lead frame 10.

The lead frame 10 may have a space in which the plurality of first electronic components 20 may be mounted and may include leads which may be connected to the plurality of first electronic components 20.

The first electronic components 20 may be various components required to perform a function of the power package module 100. The same type of the first electronic components 20 may be provided and different types of the first electronic components 20 may be provided.

The first electronic components 20 may be mounted on the lead frame 10 by an automatic process. Alternatively, the first electronic components 20 may be attached to the lead frame 10. To this end, a bonding film may be provided on a bottom surface of each of the plurality of the first electronic components 20.

At least one connection pad may be formed on a top surface of each of the plurality of the first electronic components 20.

The connection pad may be connected to the via electrode 60 formed in the filling process of the conductive material.

2) Disposing Insulating Member (S20)

In this process, the insulating member 40 may be disposed on the top surfaces of the plurality of the first electronic components 20.

The insulating member 40 may be a printed circuit board or an insulating substrate. The insulating member 40 may contact the first electronic components 20. The insulating member 40 may include the plurality of through holes 42 and pattern grooves 44. The through holes 42 may be formed in positions corresponding to the connection pads of the first electronic components 20 and the pattern grooves 44 may be formed to connect different through holes 42 to each other. For reference, the through holes 42 and the pattern grooves 44 may be formed before the insulating member 40 is disposed on the first electronic components 20, but if necessary, the through holes 42 and the pattern grooves 44 may be formed by laser processing after the insulating member 40 is disposed on the first electronic components 20.

3) Filling Conductive Material (S30)

In this process, the through holes 42 and the pattern grooves 44 may be filled with the conductive material.

The conductive material 50 may be filled in the through holes 42 and the pattern grooves 44 by a squeezing process. As the conductive material 50, a solder paste or conductive epoxy may be used. However, the conductive material 50 is not limited to the listed materials and the conductive material 50 may be substituted with any material if the material has conductivity.

Meanwhile, the conductive material 50 filled in the through holes 42 may be filled to the top surfaces of the first electronic components 20. In detail, the conductive material 50 may contact the connection pad of the first electronic component 20. The conductive material 50 filled as above may connect the first electronic components 20 and the circuit patterns 62 of the insulating member 40.

For reference, when the conductive material 50 is filled in the through holes 42 and the pattern grooves 44, hardening the conductive material 50 may be further performed.

In the manufacturing method of the power package module formed as above, since connection circuits that connect the first electronic components 20 and the lead frame 10 are simultaneously formed through the filling process of the conductive material 50, it is very advantageous to manufacture the power package module including the plurality of first electronic components 20.

A manufacturing method of the power package module according to another embodiment of the present invention will hereinafter be described with reference to FIG. 9.

The manufacturing method of the power package module according to the embodiment may include coupling a lead frame and a heat dissipating member (S12), mounting an electronic component (S14), disposing an insulating member (S20), and filling a conductive material (S30). For reference, in the listed processes, since processes S20 and S30 are the same as those of the manufacturing method of the power package module according to the aforementioned embodiment, a detailed description of the steps will be omitted.

1) Coupling Lead Frame and Heat Dissipating Member (S12)

In this process, the heat dissipating member 70 may be mounted on the lead frame 10. Alternatively, in this process, the heat dissipating member 70 may be mounted on the lead frame 10. Moreover, this process may be performed after mounting the electronic component if necessary (S14).

In this process, the lead frame 10 and the heat dissipating member 70 may be coupled or bonded so as not to be separated from each other. However, the lead frame 10 and the heat dissipating member 70 may be separately coupled to each other if necessary.

2) Mounting Electronic Component (S14)

In this process, the plurality of first electronic components 20 may be mounted on the top surface of the heat dissipating member 70.

The first electronic components 20 may be mounted to correspond to the through holes 42 formed in the insulating member 40. However, in the case in which through holes 42 are formed after the insulating member 40 is disposed on the top surfaces of the first electronic components 20, the first electronic components 20 may be arbitrarily disposed.

In this process, the first electronic components 20 may be adhered to the heat dissipating member 70. To this end, applying an adhesive to the bottom surface of each of the first electronic components 20 may additionally be performed.

In the manufacturing method of the power package module configured as above, since the heat dissipating member 70 and the first electronic components 20 are directly connected to each other, a heat dissipation effect of the power package module may be significantly increased.

As set forth above, according to the embodiments of the present invention, the lead frame and the electronic components can be easily connected to each other by using a conductive material.

Accordingly, electrical bonding reliability between the lead frame and the electronic components can be improved.

While the present invention has been shown and described in connection with the embodiments, it will be apparent to those skilled in the art that modifications and variations can be made without departing from the spirit and scope of the invention as defined by the appended claims.

What is claimed is:

1. A power package module, comprising:
a lead frame;
at least one first electronic component mounted on the lead frame; and
an insulating member disposed on a first surface of the first electronic component and having a via electrode connected to the first electronic component,
wherein the via electrode extends to the first surface.

2. The power package module of claim 1, wherein the insulating member includes a plurality of through holes, each being provided for forming the via electrode.

3. The power package module of claim 1, wherein the insulating member is a printed circuit board (PCB).

4. The power package module of claim 1, wherein the insulating member includes a circuit pattern connecting the via electrode and the lead frame.

5. The power package module of claim 4, wherein the via electrode is formed of a conductive material that integrally connects the first electronic component and the circuit pattern.

6. The power package module of claim 1, wherein the insulating member includes a through hole for forming the via electrode and a pattern groove for forming a circuit pattern.

7. The power package module of claim 6, wherein the through hole and the pattern groove are filled with a conductive material.

8. The power package module of claim 1, wherein the insulating member has a second electronic component mounted thereon.

9. The power package module of claim 8, wherein the second electronic component includes a passive element.

10. The power package module of claim 1, further comprising a heat dissipating member attached to the lead frame to dissipate heat generated from the electronic component to the outside.

11. A power package module, comprising:
a heat dissipating member;
at least one first electronic component mounted on the heat dissipating member;
an insulating member disposed on a first surface of the first electronic component and having a via electrode connected to the first electronic component; and
a lead frame connected to the insulating member,
wherein the via electrode extends to the first surface.

12. The power package module of claim 11, wherein the insulating member includes a plurality of through holes, each being provided for forming the via electrode.

13. The power package module of claim 11, wherein the insulating member is a PCB.

14. The power package module of claim 11, wherein the insulating member includes a circuit pattern connecting the via electrode and the lead frame.

15. The power package module of claim 14, wherein the via electrode is formed of a conductive material that integrally connects the first electronic component and the circuit pattern.

16. The power package module of claim 11, wherein the insulating member includes a through hole for forming the via electrode and a pattern groove for forming a circuit pattern.

17. The power package module of claim 16, wherein the through hole and the pattern groove are filled with a conductive material.

18. The power package module of claim 11, wherein the insulating member has a second electronic component mounted thereon.

19. The power package module of claim 18, wherein the second electronic component includes a passive element.

20. A manufacturing method of a power package module, the manufacturing method comprising:
mounting at least one electronic component on a lead frame;
disposing a circuit pattern connected to the lead frame and an insulating member provided with a through hole on a first surface of the electronic component; and
forming a via electrode connecting the electronic component and the circuit pattern by filling the through hole with a conductive material.

21. The manufacturing method of claim 20, wherein the through hole is filled with the conductive material by a squeezing process.

22. A manufacturing method of a power package module, comprising:
mounting a heat dissipating member on a lead frame;
mounting at least one electronic component on the heat dissipating member;
disposing an insulating member provided with a pattern groove and a through hole on a first surface of the electronic component; and
forming a connection circuit connecting the electronic component and the lead frame by filling the pattern groove and the through hole with a conductive material.

23. The manufacturing method of claim 22, wherein the pattern groove and the through hole are filled with the conductive material by a squeezing process.
